(19) United States
(12) Patent Application Publication
(10) Pub. No.: US 2024/0321722 A1
(43) Pub. Date: Sep. 26, 2024

(54) SEMICONDUCTOR PACKAGE, AND REDISTRIBUTION SUBSTRATE FOR SEMICONDUCTOR PACKAGE AND MANUFACTURING METHOD THEREOF

(71) Applicant: SAMSUNG ELECTRONICS CO., LTD., SUWON-SI (KR)

(72) Inventors: YOONYOUNG JEON, SUWON-SI (KR); YOUNGMIN KIM, SUWON-SI (KR); JOON SEOK OH, SUWON-SI (KR); CHANGBO LEE, SUWON-SI (KR)

(21) Appl. No.: 18/481,872

(22) Filed: Oct. 5, 2023

(30) Foreign Application Priority Data
Mar. 22, 2023 (KR) 10-2023-0037294

(51) Int. Cl. H01L 23/498; H01L 21/48

(52) U.S. Cl. CPC H01L 23/49894; H01L 21/4857; H01L 23/49816; H01L 23/49822; H01L 24/16; H01L 2224/16227

(57) ABSTRACT

A semiconductor package includes a semiconductor chip, and a redistribution structure connected to the semiconductor chip. The redistribution structure may include an under bump pattern, a first redistribution layer disposed on the under bump pattern and including a first redistribution pad, a partition disposed inside the first redistribution pad and including a material that is different from that of the first redistribution pad, a contact via disposed on the first redistribution pad and the partition, and a second redistribution layer including a second redistribution pad disposed on the contact via.

### CROSS-REFERENCE TO RELATED APPLICATION

This application claims priority under 35 U.S.C. § 119 to Korean Patent Application No. 10-2023-0037294, filed in the Korean Intellectual Property Office on Mar. 22, 2023, the entire contents of which are herein incorporated by reference in their entirety.

### TECHNICAL FIELD

The present disclosure relates to a semiconductor package, and more specifically to a semiconductor package and a redistribution substrate for the semiconductor package and a manufacturing method thereof.

### DISCUSSION OF THE RELATED ART

A semiconductor package may include a redistribution structure for implementing a semiconductor chip into a form that is suitable for use in an electronic product. For example, in a fan-out semiconductor package, a redistribution structure is used so that connection terminals are disposed in an area other than an area in which a semiconductor chip is disposed. According to this, a sufficient number of the connection terminals may be provided while reducing the size of the semiconductor package.

When the redistribution structure is relatively larger, the size and/or shape of the redistribution structure may be undesirably changed during manufacturing. Productivity and reliability of the redistribution structure or a semiconductor package including the redistribution structure may then be deteriorated as a result.

### SUMMARY

A semiconductor package includes a semiconductor chip, and a redistribution structure connected to the semiconductor chip. The redistribution structure includes an under bump pattern, a first redistribution layer disposed on the under bump pattern and including a first redistribution pad, a partition disposed inside the first redistribution pad and including a material that is different from that of the first redistribution pad, a contact via disposed on the first redistribution pad and the partition, and a second redistribution layer including a second redistribution pad disposed on the contact via.

A redistribution substrate for a semiconductor package includes an under bump pattern. A first redistribution layer is disposed on the under bump pattern and includes a first redistribution pad. A separation insulating portion is disposed inside the first redistribution pad and includes an insulating material having a smaller thermal shrinkage rate than that of the first redistribution pad. A contact via is disposed on the first redistribution pad and the separation insulating portion. A second redistribution layer includes a second redistribution pad connected to the contact via.

A manufacturing method of a redistribution substrate for a semiconductor package includes forming at least a portion of an under bump pattern on a first insulating layer. A mask layer including a first mask portion on the under bump pattern is formed. A first redistribution layer including a first redistribution pad disposed on a portion other than the first mask portion is formed on the under bump pattern. The mask layer is removed. A partition is formed in a portion from which the first mask portion is removed inside the first redistribution pad. A contact via is formed on the first redistribution pad and the partition.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a schematic cross-sectional view of a semiconductor package according to an embodiment;

FIG. 2 is an enlarged cross-sectional view of portion “A” of FIG. 1;

FIG. 3 is a top plan view of a first redistribution pad included in the semiconductor package illustrated in FIG. 1;

FIG. 4A and FIG. 4B are top plan views of a first redistribution pad according to various modifications;

FIG. 5A to FIG. 5H are schematic cross-sectional views of a manufacturing method of a semiconductor package according to an embodiment;

FIG. 6 is a schematic cross-sectional view of a semiconductor package according to an embodiment; and

FIG. 7A to FIG. 7D are schematic cross-sectional views of a manufacturing method of a semiconductor package according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below an element, and does not necessarily mean disposed on an upper side of the element based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

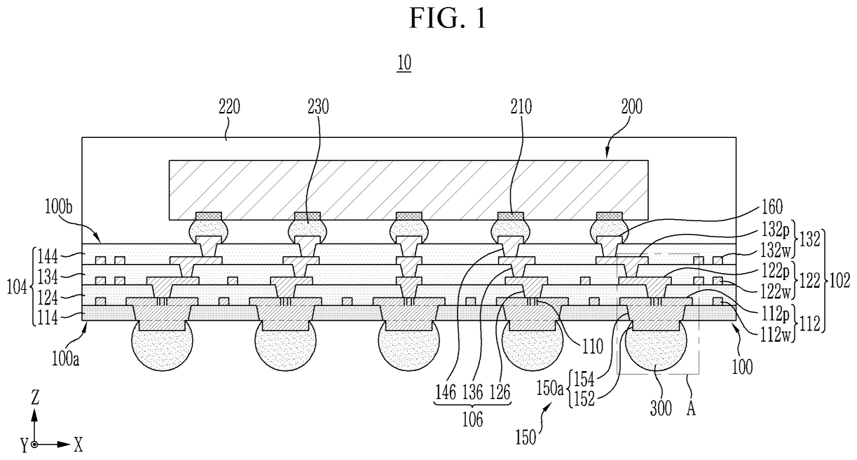

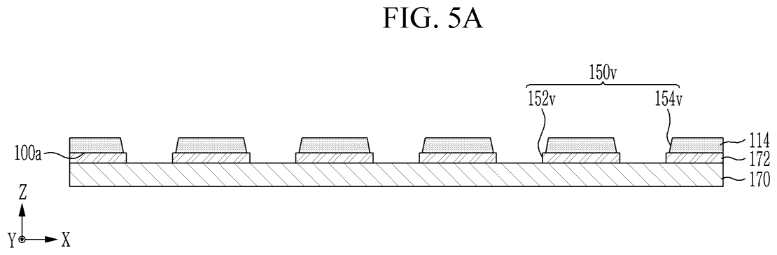

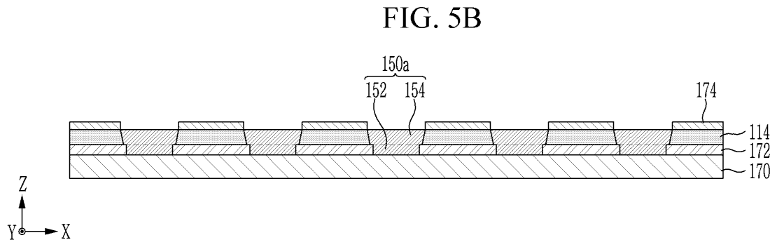

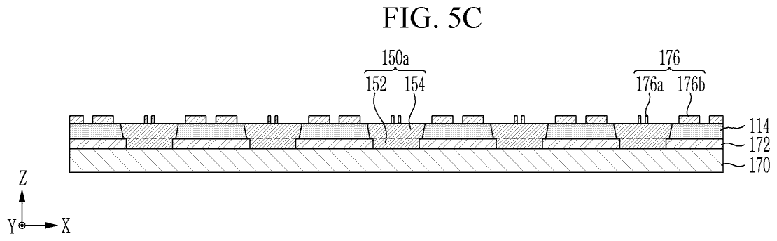

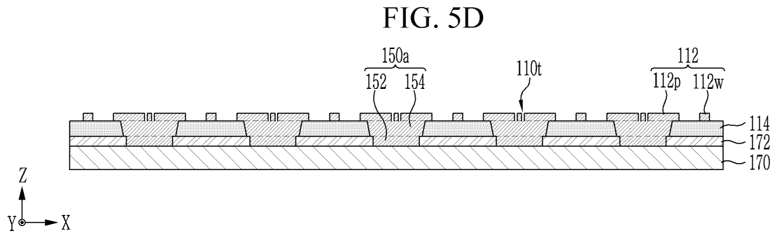

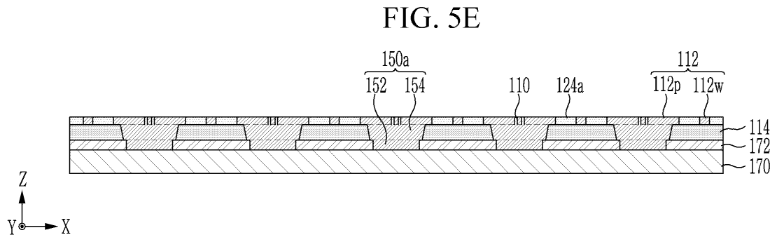

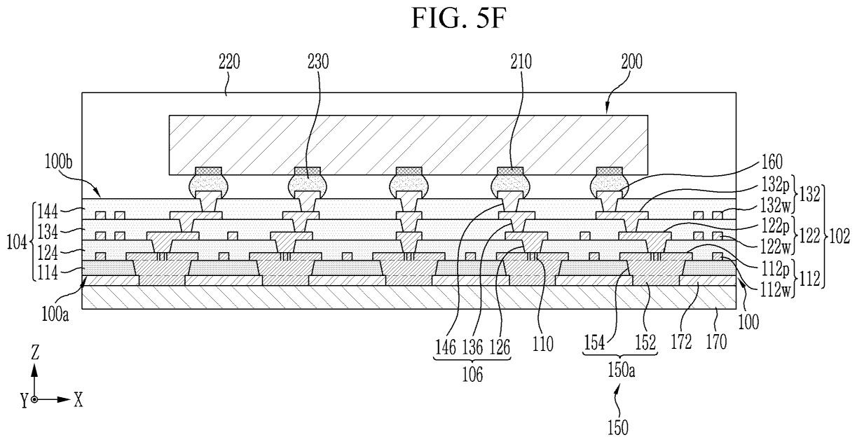

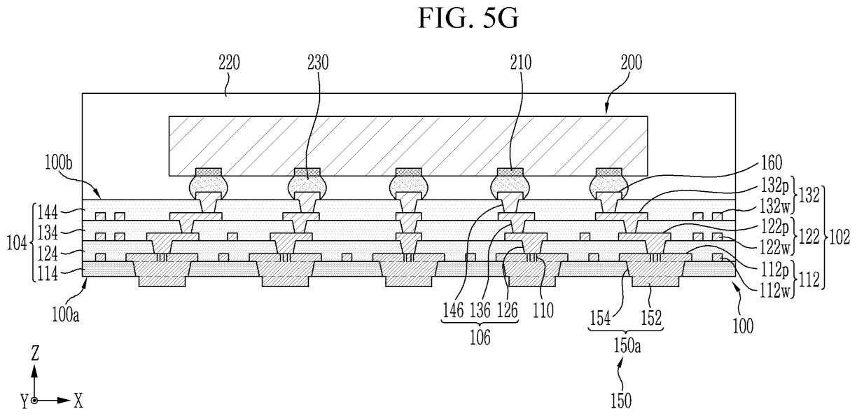

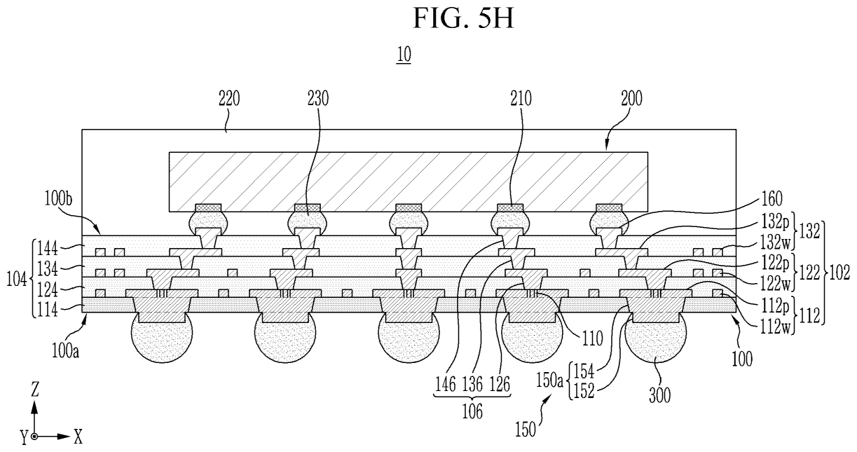

Hereinafter, a semiconductor package and a manufacturing method thereof according to an embodiment will be described in detail with reference to FIG. 1 to FIG. 4A and FIG. 4B, and FIG. 5A to FIG. 5H.

FIG. 1 illustrates a schematic cross-sectional view of a semiconductor package according to an embodiment.

Referring to FIG. 1, a semiconductor package 10, according to an embodiment, includes a semiconductor chip 200 and a redistribution structure 100 connected to the semiconductor chip 200, and may further include a connection bump 300, a sealant 220, and the like. This arrangement is described in more detail as follows.

In an embodiment, the semiconductor chip 200 may be a memory chip that stores data, a non-memory chip that computes, processes, or controls information, and a composite semiconductor chip in which a memory part and a non-memory part are combined, or may be a plurality of chips. For example, the memory chip may be a volatile memory such as a dynamic random access memory (DRAM) and a static random access memory (SRAM), and a non-volatile memory such as a NAND flash memory system. For example, the non-memory chip or the composite semiconductor chip may be a central processing unit (CPU), a graphics processing unit (GPU), a neural processing unit (NPU), a microcontroller unit (MCU), an application processor (AP), an application-specific integrated circuit (ASIC), an image sensor, and the like. In this way, the embodiment is not necessarily limited by any one type of semiconductor chip 200.

The redistribution structure 100 connected to the semiconductor chip 200 may form a fan-out structure that redistributes a connection pad 210 of the semiconductor chip 200 to a fan-out area, or may electrically connect a plurality of chips forming the semiconductor chip 200. The fan-out area may be an area that does not overlap the semiconductor chip 200, when viewed in a plan view. When the fan-out structure is formed using the redistribution structure 100, an area in which a first connection pad 150 to which the connection bump 300 is connected may be formed wider than an area in which the semiconductor chip 200 is disposed. Accordingly, even if the size of the semiconductor chip 200 is reduced, a sufficient number of the first connection pads 150 may be provided. However, the embodiment is not necessarily limited thereto, and various modifications are possible, such as the redistribution structure 100 forming a fan-in structure.

The redistribution structure 100 is a portion that redistributes signals in the semiconductor package 10, and may be referred to as a redistribution substrate or a redistribution portion. A first surface (hereinafter referred to as a lower surface) 100a of the redistribution structure 100 may be exposed to the outside, and the semiconductor chip 200 may be mounted on a second surface (hereinafter referred to as an upper surface) 100b of the redistribution structure 100. Here, the upper portion or upper surface of the redistribution structure 100 may be a portion or surface of the redistribution structure 100 close to the semiconductor chip 200, and the lower portion or lower surface of the redistribution structure 100 may be a portion or surface of the redistribution structure 100 disposed far from the semiconductor chip 200. For example, the lower surface 100a of the redistribution structure 100 may be defined as a lower surface or an outer surface of the insulating layer 104 provided in the redistribution structure 100, and the upper surface 100b of the redistribution structure 100 may be defined as an upper surface of the insulating layer 104 provided in the redistribution structure 100.

In an embodiment, the semiconductor chip 200 may be mounted on the redistribution structure 100 by using a flip-chip bonding method. For example, the connection pad 210 may be disposed on the lower surface of the semiconductor chip 200. A connector 230 may be disposed between the connection pad (for example, a second connection pad 160) disposed on the upper surface 100b of the redistribution structure 100 and the connection pad 210 disposed on the lower surface of the semiconductor chip 200 to electrically connect the redistribution structure 100 and the semiconductor chip 200. The connector 230 may have a land, ball, or pin shape. The connector 230 may include, for example, tin (Sn), or an alloy (for example, a Sn—Ag—Cu alloy) containing tin (Sn). The embodiment is not necessarily limited thereto, and the semiconductor chip 200 may be mounted on the redistribution structure 100 by a wire bonding method.

The sealant 220 may be disposed on the upper surface 100b of the redistribution structure 100 to seal at least a portion of the semiconductor chip 200 and/or the redistribution structure 100. Although FIG. 1 illustrates that the sealant 220 entirely covers the semiconductor chip 200 and the upper surface 100b of the redistribution structure 100, the embodiment is not necessarily limited thereto. The sealant 220 may include a thermosetting resin such as an epoxy resin, a thermoplastic resin such as polyimide, a resin including an inorganic filler and/or a glass fiber, an epoxy molding compound (EMC), and the like, but the embodiment is not necessarily limited to the material of the sealant 220.

In an embodiment, the redistribution structure 100 may include a plurality of redistribution layers 102 disposed with the insulating layer 104 interposed therebetween, and the connection pads 150 and 160 electrically connected to the plurality of redistribution layers 102 and connected to the outside. The plurality of redistribution layers 102 may be connected to configure a desired circuit through a contact via 106 penetrating the insulating layer 104 to connect the plurality of redistribution layers 102 and the connection pads 150 and 160.

For example, the plurality of redistribution layers 102 may perform various functions according to a design. For example, the plurality of redistribution layers 102 may include a ground pattern, a power pattern, and a signal pattern. The signal pattern may include various signals other than signals applied to the ground pattern, the power pattern, and the like, for example, a data signal. The contact via 106 may penetrate one insulating layer 104 to connect the redistribution layer 102 or the second connection pad 160 disposed on the insulating layer 104 and the redistribution layer 102 disposed below the insulating layer 104, or to connect the redistribution layer 102 disposed on the insulating layer 104 and the redistribution layer 102 or the first connection pad 150 disposed below the insulating layer 104. The contact via 106 may include a ground via, a power via, and a signal via.

The connection pads 150 and 160 may include the first connection pad 150 disposed on the lower surface 100a of the redistribution structure 100 and the second connection pad 160 disposed on the upper surface 100b of the redistribution structure 100. Here, the upper surface 100b of the redistribution structure 100 may form a connection surface on which the semiconductor chip 200 is disposed, and the lower surface 100a of the redistribution structure 100 may form an outer surface for connection to the connection bump 300 and an external circuit. For example, the first connection pad 150 disposed on the upper surface 100b of the redistribution structure 100 may be a pad in which a connector 230 for connection to the semiconductor chip 200 is disposed, and the second connection pad 160 disposed on the lower surface of the redistribution structure 100 may be a pad in which the connection bump 300 for connection to a package substrate is disposed.

In an embodiment, the first connection pad 150 may be an under bump pattern 150a or an under bump metal (UBM) to which the connection bump 300 is connected (for example, directly connected). In an exemplary embodiment, the first connection pad 150 or under bump pattern 150a may include an under bump pad 152 exposed on the lower surface 100a so that the connection bump 300 may be connected, and an under bump via 154 penetrating the first insulating layer 114.

For example, the under bump pad 152 and the under bump via 154 are formed as an integral structure formed in the same process, and the outer surface of the under bump pad 152 may have a shape protruding from the outer surface of the first insulating layer 114 or the lower surface 100a of the redistribution structure 100. In this case, the portion protruding from the outer surface of the first insulating layer 114 or the lower surface 100a of the redistribution structure 100 may form the under bump pad 152, and the portion penetrating the first insulating layer 114 may form the under bump via 154. When the under bump pad 152 is formed together with the under bump via 154 as described above, the process may be simplified. In addition, when the under bump pad 152 protrudes from the first insulating layer 114, stability may be increased when connected to the connection bump 300.

In the drawing, it is illustrated that the size of the under bump pad 152 is smaller than that of the under bump via 154. According to this, when the under bump pad 152 and the under bump via 154 are formed together in the same process, the under bump pads 152 may be stably formed.

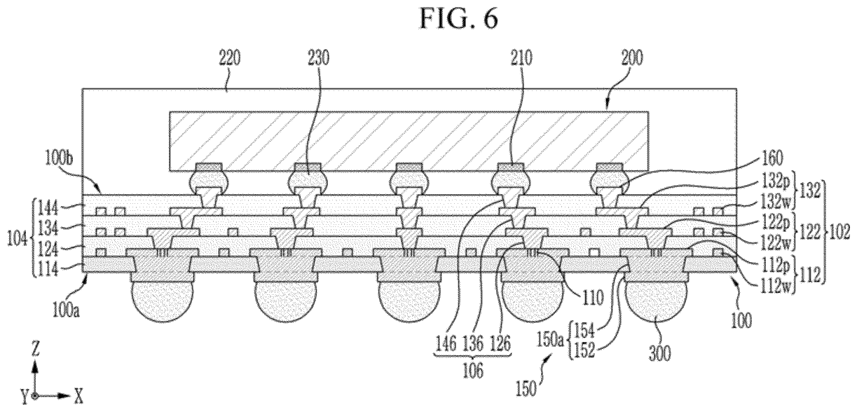

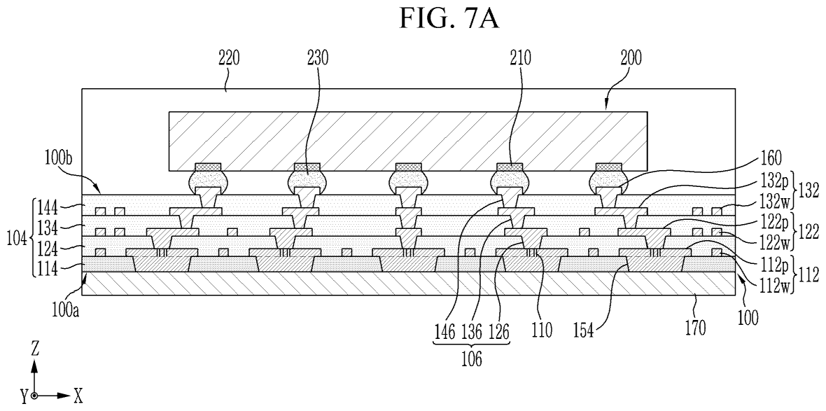

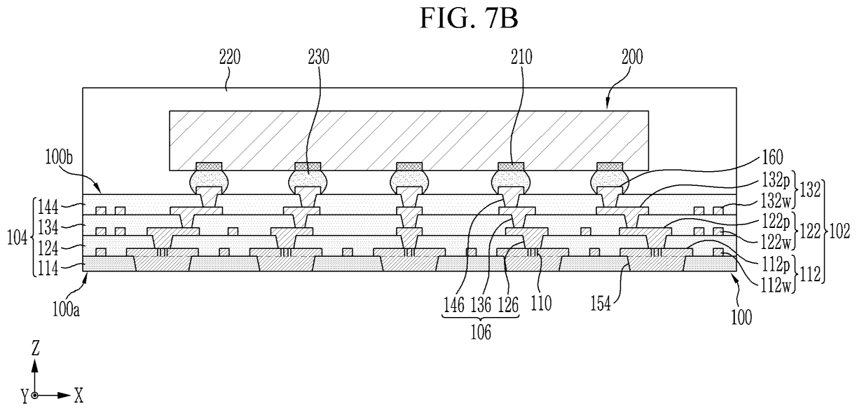

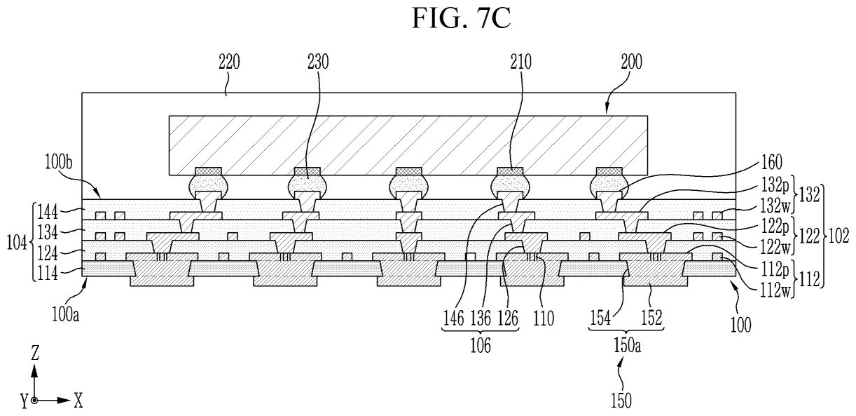

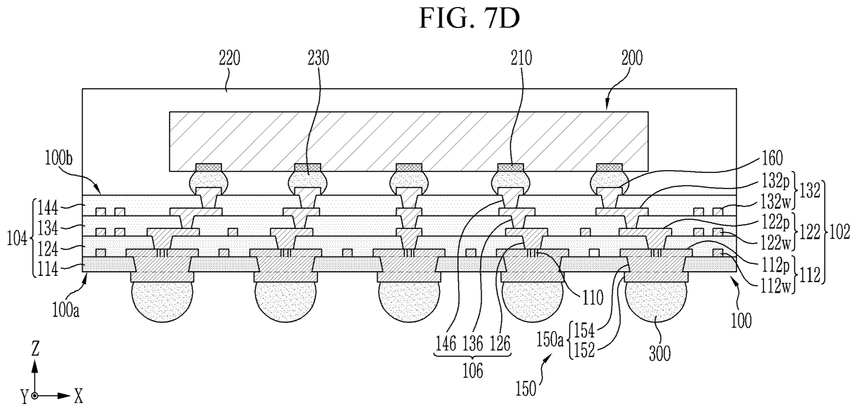

However, the embodiment is not necessarily limited thereto, and the size of the under bump pad 152 may be equal to or larger than that of the under bump via 154. However, the embodiment is not necessarily limited thereto. Accordingly, the under bump pad 152 and the under bump via 154 may be formed in separate processes, or may be separate portions having different materials or characteristics. For example, after forming the under bump pad 152, the under bump via 154 may be formed. As an example, after forming the under bump via 154, the under bump pad 152 may be formed on the lower surface 100a of the first insulating layer 114. Other approaches will be described in detail later with reference to FIG. 6 and FIG. 7A to FIG. 7D. Alternatively, the outer surface of the under bump pad 152 may be disposed on the same plane as the lower surface 100a of the first insulating layer 114, and the under bump pattern 150a may be the under bump via 154 so that the under bump via 154 may form an under bump pad. Alternatively, a separate insulating layer exposing the under bump pad 152 may be disposed on the outer surface of the first insulating layer 114. As described above, various modifications are possible for the shape and structure of the under bump pattern 150a.

The plurality of redistribution layers 102 may include a first redistribution layer 112 disposed on the under bump pattern 150a and a second redistribution layer 122 disposed on the first redistribution layer 112. In addition, one or a plurality of third redistribution layers 132 disposed on the second redistribution layer 122 may be further included. A plurality of insulating layers 104 supporting the plurality of redistribution layers 102 may be disposed between the plurality of redistribution layers 102 or above or below the plurality of redistribution layers 102. The contact via 106 may be formed on the insulating layer 104 to connect the plurality of redistribution layers 102 in a desired path.

Here, the first redistribution layer 112 may refer to a redistribution layer including a first redistribution pad 112p disposed on the first insulating layer 114 and connected to the under bump pattern 150a (for example, connected to the under bump pad 152 through the under bump via 154), and the second redistribution layer 122 may refer to a redistribution layer disposed on the second insulating layer 124 covering the first redistribution layer 112 and connected to the first redistribution pad 112p (for example, connected to the first redistribution pad 112p through the second contact via 126). The third redistribution layer 132 may refer to a redistribution layer disposed between the second redistribution layer 122 and the second connection pad 160.

For example, the first redistribution layer 112 includes the first redistribution pad 112p to which the under bump pattern 150a and the second contact via 126 are connected, and may further include a first wire portion 112w connected to the first redistribution pad 112p to configure a desired circuit wire. The second redistribution layer 122 includes a second redistribution pad 122p to which the second contact via 126 and the third contact via 136 are connected, and may further include a second wire portion 122w connected to the second redistribution pad 122p to configure a desired circuit wire. The third redistribution layer 132 includes a third redistribution pad 132p to which the third contact vias 136 and the fourth contact vias 146 are connected, and may further include a third wire portion 132w connected to the third redistribution pad 132p to configure a desired circuit wire.

In addition, the insulating layer 104 may include a first insulating layer 114 disposed under the first redistribution layer 112 and in which at least a portion of the under bump pattern 150a is disposed, a second insulating layer 124 disposed under the second redistribution layer 122 on the first insulating layer 114, one or a plurality of third insulating layers 134 disposed under one or a plurality of third redistribution layers 132 on the second insulating layer 124, and a fourth insulating layer 144 disposed under the second connection pad 160 on the third insulating layer 134. In this way, the insulating layer 104 may be stacked in a thickness direction (e.g., a Z-axis direction in the drawing) of the redistribution structure 100 to be configured as a plurality of insulating layers provided between the plurality of redistribution layers 102 and/or above or below the plurality of redistribution layers 102.

In this case, the under bump via 154 passing through the first insulating layer 114 to connect the under bump pad 152 and the first redistribution layer 112 may be referred to as a first contact via, and the contact vias 106 penetrating the second insulating layer 124, the third insulating layer 134, and the fourth insulating layer 144, respectively, may be referred to as the second contact via 126, the third contact via 136, and the fourth contact via 146. This terminology is only for distinguishing from each other, and the embodiment is not necessarily limited thereto.

For example, at least a portion of the contact via 106 and at least a portion of the redistribution layer 102 or the second connection pad 160 may be formed together in the same process to have a single body. For example, the second contact via 126 and the second redistribution layer 122 may be formed together in the same process, or the third contact via 136 and the third redistribution layer 132 may be formed together in the same process, and/or the fourth contact via 146 and the second connection pad 160 may be formed together in the same process. Alternatively, the second contact via 126 may be formed separately from the second redistribution layer 122 in a different process, or the third contact via 136 may be formed separately from the third redistribution layer 132 in a different process, and/or the fourth contact via 146 may be formed separately from the second connection pad 160 in a different process. For example, the embodiment is not necessarily limited to the formation order or structure of the contact via 106 and the redistribution layer 102 or the second connection pad 160.

In the drawing, it is illustrated that the first insulating layer 114, the third insulating layer 134, and the fourth insulating layer 144 are each configured as one layer, and as another example, the first insulating layer 114, the third insulating layer 134, and/or the fourth insulating layer 144 may include a plurality of layers formed by different processes. In this case, the boundaries of the plurality of layers forming the first insulating layer 114, the third insulating layer 134, and/or the fourth insulating layer 144 may or might not be identified in the final structure.

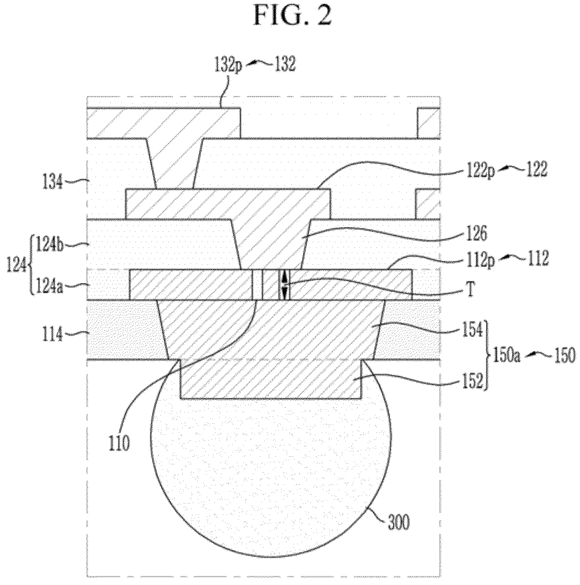

In an embodiment, the second insulating layer 124 may include a lower insulating layer (e.g., reference numeral 124a in FIG. 2 may be the same) disposed on the same layer as the first redistribution layer 112, and an upper insulating layer disposed between the first redistribution layer 112 and the second redistribution layer 122 (e.g., reference numeral 124b in FIG. 2 might be the same). This will be described in more detail later.

Here, the disposing of the lower insulating layer 124a and the first redistribution layer 112 on the same layer may mean that at least one of the upper and lower surfaces of the lower insulating layer 124a is disposed at the same position as at least one of the upper and lower surfaces of the first redistribution layer 112 in the thickness direction of the redistribution structure 100 (e.g., Z-axis direction in the drawing). According to this, the upper surface of the lower insulating layer 124a and the upper surface of the first redistribution layer 112 may be disposed on the same plane, and/or the lower surface of the lower insulating layer 124a and the lower surface of the first redistribution layer 112 may be disposed on the same plane. In addition, in the thickness direction of the redistribution structure 100 (e.g., Z-axis direction in the drawing), the lower surface of the upper insulating layer 124b may be disposed at the same position as the upper surface of the first redistribution layer 112, and/or the upper surface of the upper insulating layer 124b may be disposed at the same position as the lower surface of the second redistribution layer 122. According to this, the lower surface of the upper insulating layer 124b and the upper surface of the first redistribution layer 112 may be disposed on the same plane, and/or the upper surface of the upper insulating layer 124b and the lower surface of the second redistribution layer 122 may be disposed on the same plane.

In an embodiment, the lower insulating layer 124a and the upper insulating layer 124b may be formed by different processes. This will be described in more detail later in the manufacturing process. Even when the lower insulating layer 124a and the upper insulating layer 124b are formed in different processes, the lower insulating layer 124a and the upper insulating layer 124b may or might not have a boundary in the final structure.

For brief illustration and clear understanding, in the drawings and the following description, as an example, the plurality of redistribution layers 102 include the first redistribution layer 112, the second redistribution layer 122, and one third redistribution layer 132, and the insulating layer 104 includes the first insulating layer 114, the second insulating layer 124, one third insulating layer 134, and one fourth insulating layer 144. However, the embodiment is not necessarily limited thereto. Accordingly, the second redistribution layer 122 and the second connection pad 160 may be connected through the fourth contact via 146 without including the third redistribution layer 132 and the third insulating layer 134, or a plurality of third redistribution layers 132 may be provided. When the plurality of third redistribution layers 132 are provided, the shape and disposition of the pads and wires forming the plurality of third redistribution layers 132 and the disposition of the third contact via 136 respectively connected to the plurality of third redistribution layers 132 may be different from each other.

The second connection pad 160 is a pad disposed on the fourth insulating layer 144, and in the drawing, the second connection pad 160 has a shape protruding from the upper surface 100b of the redistribution structure 100. According to this, the connection stability of the connector 230 disposed on the second connection pad 160 may be increased. However, the embodiment is not necessarily limited thereto, and the upper surface of the second connection pad 160 may be disposed on the same plane as the upper surface 100b of the redistribution structure 100. Various other variations are possible.

The insulating layer 104 may include an insulating material. The insulating material may include a thermosetting resin such as an epoxy resin, a thermoplastic resin such as polyimide, or a resin including an inorganic filler and/or a glass fiber. Alternatively, the insulating layer 104 may include a photosensitive resin such as photoimageable dielectric (PID). When the insulating layer 104 includes the PID, each insulating layer 104 may be thinly formed and the contact via 106 may be finely formed, and the redistribution layer 102 may be stably formed by a plating process. The plurality of insulating layers 104 may include the same material or different materials, and a boundary between the plurality of insulating layers 104 might not be clear depending on a process.

The under bump pattern 150a, the plurality of redistribution layers 102, or the contact via 106 may include, for example, a metal material including copper (Cu), aluminum (Al), silver (Ag), tin (Sn), gold (Au), nickel (Ni), lead (Pb), titanium (Ti), or an alloy thereof. The contact via 106 may be a filled via in which a metal material is filled in the via hole formed in the insulating layer 104 or a conformal via in which a metal material is formed along an inner wall of the via hole. The under bump pattern 150a, the plurality of redistribution layers 102, or the contact vias 106 may include the same metal material or different metal materials.

In an embodiment, the side surface of the under bump via 154 or contact via 106 may be an inclined surface or tapered surface that gradually decreases in width or size from the upper surface 100b of the redistribution structure 100 toward the lower surface 100a thereof. Since the under bump vias 154 and the contact vias 106 are sequentially formed, the side surfaces of the under bump via 154 and the contact via 106 may be configured as inclined surfaces having the same inclined direction.

From this, it can be seen that the semiconductor package 10, according to an embodiment, has a chip last structure in which the semiconductor chip 200 is mounted after forming at least a portion of the redistribution structure 100 including the redistribution layer 102, the insulating layer 104, and the like. With the chip last structure as described above, since the defective redistribution structure 100 may be discarded before attaching the semiconductor chip 200, problems such as the semiconductor chip 200 having to be discarded together due to the defect in the redistribution structure 100 may be prevented.

In an embodiment, the under bump pattern 150a connected to the connection bump 300 may have a size or width that is greater than that of the contact via 106, the inner redistribution pad (for example, the second redistribution pad 122p and the third redistribution pad 132p), and the second connection pad 160. In addition, the first redistribution pad 112p of the first redistribution layer 112 connected to the under bump pattern 150a may have a size or width that is greater than that of the contact via 106, the inner redistribution pad 122p and the third redistribution pad 132p, and the second connection pad 160. As described above, the under bump pattern 150a has a relatively large size, so that the connection bump 300 may be stably connected to the under bump pattern 150a, and the first redistribution pad 112p connected to the under bump pattern 150a has a relatively large size, so that the first redistribution pad 112p may be stably connected to the under bump pattern 150a. This is because the contact via 106 and the inner redistribution pad may have a relatively small size that is sufficient to implement only an electrical connection structure that may form the desired redistribution structure.

For example, the first redistribution pad 112p may have a larger size or width than the under bump pattern 150a. This is to stably connect the under bump pattern 150a to the first redistribution pad 112p. Here, the size or width of the first redistribution pad 112p and the under bump pattern 150a may be a maximum size or a maximum width. However, the embodiment is not necessarily limited thereto, and the first redistribution pad 112p may have a size that is equal to or smaller than that of the under bump pattern 150a.

As such, the first redistribution pad 112p has a larger size than the inner redistribution pad, and may be, for example, the largest portion of the redistribution structure 100. For example, the entire length (e.g., diameter or width) of the first redistribution pad 112p may be 100 μm to 500 μm (for example, 100 μm to 300 μm), and the length (e.g., diameter or width) of the inner redistribution pad may be 10 μm to 50 μm. However, the embodiment is not necessarily limited thereto, and numerous variations are possible. Here, the length may be the largest length among distances between outer edges of the first redistribution pad 112p.

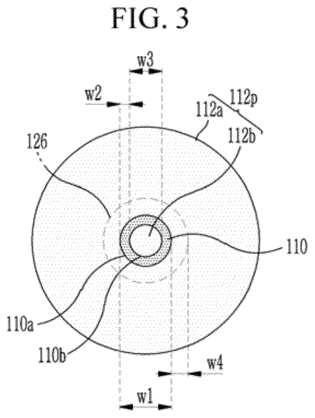

In an embodiment, a partition 110 may be provided inside the first redistribution pad 112p to reduce a metal shrink path of the first redistribution pad 112p. This will be described in more detail with reference to FIG. 2 and FIG. 3.

FIG. 2 illustrates an enlarged cross-sectional view of portion “A” of FIG. 1, and FIG. 3 illustrates a top plan view of the first redistribution pad 112p included in the semiconductor package 10 illustrated in FIG. 1.

For reference, a boundary of a bottom surface of the second contact via 126 disposed on the first redistribution pad 112p is indicated by a dotted line in FIG. 3.

Referring to FIG. 2 and FIG. 3, a partition 110 having a material that is different from a metallic material forming the first redistribution pad 112p may be disposed inside the first redistribution pad 112p. The partition 110 may be disposed inside the first redistribution pad 112p to reduce the metal shrink path of the first redistribution pad 112p.

In an embodiment, the partition 110 may include or be made of a material having a lower thermal shrinkage rate than the material forming the first redistribution pad 112p. Here, the thermal shrinkage rate means the degree of shrinkage in a process performed at a temperature higher than room temperature, and for example, it may be the degree of shrinkage at the curing temperature of the curing process that hardens (for example, thermal-cures) at least a portion of the insulating layer 104. For example, in the curing process of curing at least a portion (for example, the partition 110 and/or the lower insulating layer 124a) of the insulating layer 104, a shrinkage rate of the partition 110 due to a temperature higher than room temperature may be smaller than a shrinkage rate of the first redistribution pad 112p.

For example, the partition 110 may be made of an insulating material. This is because the insulating material has a smaller thermal shrinkage rate than the metal forming the first redistribution pad 112p to prevent a problem caused by metal shrinkage and is a material that does not undesirably affect the redistribution structure 100. When the partition is made of a metal material, a metal bond is formed between the first redistribution pad 112p and the partition, so that it is difficult for the partition to effectively prevent shrinkage of the first redistribution pad 112p.

For example, the partition 110 may be made of the same insulating material as a portion of the second insulating layer 124 disposed below the second redistribution layer 122 above the first insulating layer 114. More specifically, the partition 110 may be disposed on the same layer as the lower insulating layer 124a of the second insulating layer 124 and made of the same material as the lower insulating layer 124a. For example, the lower insulating layer 124a of the second insulating layer 124 and the partition 110 may be formed through the same process. Then, the partition 110 may be formed through a simple process.

For example, a thickness T of the partition 110 may be substantially the same as that of the lower insulating layer 124a. Here, substantially the same may be the degree to which it may be recognized that it has a process error (for example, an error within 10%) and is formed in the same process. When the lower insulating layer 124a has a boundary distinct from the upper insulating layer 124b and the first insulating layer 114, it can also be confirmed that the thickness T of the partition 110 in the final structure is substantially the same as the thickness of the lower insulating layer 124a.

However, the embodiment is not necessarily limited thereto, and the partition 110 may be formed by a process that is different from that of the lower insulating layer 124a of the second insulating layer 124, or may be made of a material different from at least a portion of the second insulating layer 124. For example, the thermal shrinkage rate of the material forming the partition 110 may be smaller than that of the second insulating layer 124 (for example, the lower insulating layer 124a). Then, by minimizing the thermal shrinkage rate by the partition 110, problems due to shrinkage of the first redistribution pad 112p after curing may be effectively prevented.

According to an embodiment, the partition 110 may serve to divide the first redistribution pad 112p having a relatively large size. Accordingly, it may serve to reduce the metal shrinkage length of the first redistribution pad 112p. As described above, since the partition 110 is made of an insulating material and serves to separate the area of the first redistribution pad 112p to be able to reduce the metal shrink path, it may also be referred to as a separator, a separation insulator, or the like. Conventionally, the metal shrinkage entirely occurs from the first redistribution pad having a relatively large size toward the center thereof, resulting in a large amount of change at the edge of the first redistribution pad.

In an embodiment, by the partition 110 disposed in the central portion of the first redistribution pad 112p or the second contact via 126, in the central portion of the first redistribution pad 112p, the first redistribution pad 112p may be divided or disconnected to effectively reduce the metal shrink path. The relatively large metal shrinkage of the first redistribution pad 112p may be concentrated in a radial direction toward the center of the first redistribution pad 112p, while by disposing the partition 110 in the central portion, it is possible to effectively prevent the metal shrinkage concentrated in the radial direction.

In this way, when the metal shrinkage phenomenon toward the central portion of the first redistribution pad 112p is reduced, it is possible to effectively reduce the amount of change occurring at the edge portion of the first redistribution pad 112p. Accordingly, the degree of shrinkage of the metal forming the first redistribution pad 112p may be reduced or the stress caused by the metal shrinkage may be dispersed. As a result, peeling (for example, delamination) occurred between the first redistribution pad 112p and the second insulating layer 124 due to stress caused by the metal shrinkage may be effectively prevented, or propagation of cracks due to the peeling to the insulating layer 104 may be effectively prevented. Particularly, the side surface of the first redistribution pad 112p and the side surface of the lower insulating layer 124a are portions that are likely to be peeled off due to the metal shrinkage of the first redistribution pad 112p, but by minimizing the metal shrinkage of the first redistribution pad 112p, the peeling of the corresponding portion may be effectively prevented.

In an embodiment, the partition 110 may be positioned at the central portion of the first redistribution pad 112p when viewed in a plan view. This is because the central portion of the first redistribution pad 112p is a portion that may effectively reduce the metal shrink path of the first redistribution pad 112p by the partition 110. However, the embodiment is not necessarily limited thereto, and the partition 110 may be disposed at a portion that is spaced apart from the central portion of the first redistribution pad 112p, and various other modifications are possible.

For example, when viewed in a plan view, the partition 110 may be disposed inside the second contact via 126 provided in the second insulating layer 124 and inside the under bump pattern 150a. According to this, the partition 110 may have a shape entirely surrounded by the first redistribution pad 112p, the second contact via 126, and the under bump pattern 150a. For example, an entire portion of the upper surface of the partition 110 may be disposed on (for example, may be in contact with) the lower surface of the second contact via 126, an entire portion of the lower surface of the partition 110 may be disposed on (for example, may be in contact with) the upper surface of the under bump pattern 150a, and an entire portion of the side surface of the partition 110 may be disposed on (for example, may be in contact with) the side surface of the second contact via 126. Then, an entire portion of the partition 110 may have a shape surrounded by a metal material forming the first redistribution pad 112p, the second contact via 126, and the under bump pattern 150a.

In this way, when the entire portion of the partition 110 having an insulating material is surrounded by the metal material, even if the partition 110 is peeled off, it is difficult for cracks caused by the peeling to propagate to the outside. This is because the periphery of the partition 110 is made of a metal material, so the cracks caused by the peeling are difficult to propagate to the metal material. On the other hand, when peeling occurs because the insulating material and the metal material are not bonded, cracks caused by the peeling may easily propagate to the insulating material when the insulating material is disposed nearby. As described above, in an embodiment, the periphery of the partition 110 may be entirely surrounded with the metal material to block the propagation of the cracks. Accordingly, it is possible to prevent a problem of deterioration in reliability due to propagation of cracks.

In this case, the partition 110 may have a closed shape or a loop shape extending along the outer edge of the first redistribution pad 112p or the outer edge of the second contact via 126. According to this, a maximum extension length of the first redistribution pad 112p may be effectively reduced while minimizing an area of the partition 110. For example, an outer edge 110a or an inner edge 110b of the partition 110 may have the same or similar shape as the outer edge of the first redistribution pad 112p or the second contact via 126, and may have a smaller size than it.

As a result, the outer edge 110a of the partition 110 is uniformly disposed at a predetermined interval from the outer edge of the first redistribution pad 112p as a whole, so that the outer portion 112a of the first redistribution pad 112p having a uniform length may be disposed outside the outer edge 110a of the partition 110. In addition, the partition 110 has a uniform width, so that the inner edge 110b of the partition 110 may be uniformly disposed at a certain interval from the outer edge of the first redistribution pad 112p, the second contact via 126, or the partition 110. Accordingly, the inner portion 112b of the first redistribution pad 112p may be disposed inside the inner edge 110b of the partition 110.

According to this, an electrical connection path between the under bump pattern 150a and the second contact via 126 may be sufficiently secured by the outer portion 112a and the inner portion 112b of the first redistribution pad 112p. In addition, the partition 110 may have a constant width to increase structural stability. In this case, one partition 110 may be provided to sufficiently secure an electrical connection path between the under bump pattern 150a and the second contact via 126.

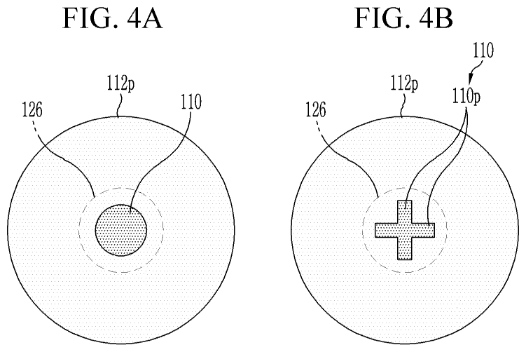

However, the embodiment is not necessarily limited thereto. As shown in FIG. 4A, the partition 110 is entirely disposed inside the outer edge of the partition 110, so that the inner portion 112b of the first redistribution pad 112p might not be provided. Alternatively, a portion in which the width of the partition 110 is changed may be provided. Alternatively, the outer or inner edge of the partition 110 may have a different shape from the outer edge of the first redistribution pad 112p. Alternatively, a plurality of partitions 110 may be provided, and the partition 110 may have various shapes other than a closed shape or loop shape.

Alternatively, as shown in FIG. 4B, the partition 110 may include a plurality of extensions 110p extending from the center thereof. The plurality of extensions 110p may have a uniform line width, may extend in a radial direction, and may be spaced apart from each other at a predetermined interval. The area of the first redistribution pad 112p may be effectively divided by the plurality of extensions 110p, so that the metal shrink path may be effectively reduced. It is illustrated that four extensions 110p are provided, but the embodiment is not necessarily limited thereto, and the number, disposition, and shape of the plurality of extensions 110p may be variously changed.

For example, the first redistribution pad 112p may have a circular shape. This is to minimize a problem such as peeling that may occur at an angled portion because no angled portion is provided at the outer edge of the first redistribution pad 112p. In consideration of this, the partition 110 may have a circular shape or a circular ring shape. However, the embodiment is not necessarily limited thereto, and the shape of the first redistribution pad 112p and the partition 110 may be variously changed to have a rounded shape, an elliptical shape, a polygonal shape, and a shape including an angular portion.

Referring back to FIG. 2 and FIG. 3, in an embodiment, an entire width W1 of the partition 110 may be greater than the thickness (T) of the partition 110. Here, the entire width W1 may be the largest length among the distances between the outer edges 110a disposed at both sides of the partition 110. According to this, problems caused by metal shrinkage of the first redistribution pad 112p may be more effectively prevented by the partition 110. However, the embodiment is not necessarily limited thereto, and the entire width W1 of the partition 110 may be equal to or smaller than the thickness T of the partition 110. According to this, the area of the first redistribution pad 112p connecting the under bump pattern 150a and the second contact via 126 is increased, so that an electrical connection path may be sufficiently secured.

For example, the entire width W1 of the partition 110 may be 3 μm to 30 μm. This range of the entire width W1 may be for increasing the effect of the partition 110 in consideration of the size (e.g., diameter or width) of the second contact via 126. However, the embodiment is not necessarily limited thereto, and the entire width W1 of the partition 110 may have various other values.

A line width W2 of the partition 110 may be greater than the thickness T of the partition 110. According to this, problems caused by metal shrinkage of the first redistribution pad 112p may be more effectively prevented by the partition 110. However, the embodiment is not necessarily limited thereto, and the line width W2 of the partition 110 may be equal to or smaller than the thickness T of the partition 110. According to this, the area of the first redistribution pad 112p connecting the under bump pattern 150a and the second contact via 126 is increased, so that an electrical connection path may be sufficiently secured.

For example, the line width W2 of the partition 110 may be 3 μm to 30 μm (for example, 3 μm to 10 μm). This line width W2 considers the effect of the partition 110 and the size (e.g., diameter or width) of the second contact via 126. However, the embodiment is not necessarily limited thereto, and the line width W2 of the partition 110 may have various other values.

A ratio of the area of the partition 100 to the area of the second contact via 126 may be 60% or lower. This range may be for sufficiently securing a connection area between the second contact via 126 and the first redistribution pad 112p. For example, the area of the partition 110 may be smaller than the connection area of the second contact via 126 and the first wire pad 112p. For example, the area of the partition 110 may be smaller than 50% of the area of the second contact via 126. However, the embodiment is not necessarily limited thereto, and numerous variations are possible.

For example, a width W3 of the inner portion 112b may be greater than the line width W2 of the partition 110. Here, the width W3 of the inner portion 112b may be the largest value among distances between edges of both sides of the inner portion 112b. According to this, it is possible to sufficiently secure the connection area between the second contact via 126 and the first redistribution pad 112p by reducing the line width W2 of the partition 110, and the partition 110 is disposed outside the inner portion 112b having a relatively large width W3, so that the metal shrink path of the first redistribution pad 112p may be effectively reduced. However, the embodiment is not necessarily limited thereto, and the width W3 of the inner portion 112b may be equal to or smaller than the line width W2 of the partition 110.

In an embodiment, the outer edge 110a of the partition 110 and the boundary of the second contact via 126 may be spaced apart from each other, and for example, a distance W4 between the outer edge 110a of the partition 110 and the boundary of the second contact via 126 may be 5% or more (for example, 10% or more) of the entire width of the second contact via 126. Here, the entire width of the second contact via 126 may be the largest width among the widths of the second contact via.

According to this, the outer edge 110a of the partition 110 is separated from the boundary of the second contact via 126 by a predetermined distance or more, so that the entire outer surface of the partition 110 may be stably surrounded by the second contact via 126, the first redistribution pad 112p, and the under bump pattern 150a. However, the embodiment is not necessarily limited thereto, and at least a portion of the outer edge 110a of the partition 110 may be adjacent to or protrude from the boundary of the second contact via 126.

According to an embodiment, the partition 110 is disposed inside the relatively large first redistribution pad 112p connected to the under bump pattern 150a, so that shrinkage of the first redistribution pad 112p and stress caused thereby may be minimized. Accordingly, peeling between the first redistribution pad 112p and the insulating layer 104, crack propagation caused thereby, and the like may be prevented, thereby preventing defects in the redistribution structure 100. Accordingly, productivity and reliability of the redistribution structure 100 and the semiconductor package 10 including the same may be increased. In this case, since the semiconductor package 10 has a chip last structure, productivity of the redistribution structure 100 and the semiconductor package 10 including the same may be further increased.

In the drawing, it is illustrated that the upper surfaces of the lower insulating layer 124a and the partition 110 are disposed on the same plane as the upper surface of the first redistribution layer 112. However, the embodiment is not necessarily limited thereto, and the upper surface of at least one of the lower insulating layer 124a and the partition 110 may be disposed lower or higher than the upper surface of the first redistribution layer 112. This may be due to process errors or differences in the manufacturing process.

In the above description, it is described as an example that the first redistribution pad 112p has a larger size than the second redistribution pad 122p, the third redistribution pad 132p, and the second connection pad 160 to be stably connected to the under bump pattern 150a. However, the embodiment is not necessarily limited thereto. Accordingly, at least one of the second redistribution pad 122p, the third redistribution pad 132, and the second connection pad 160 may have a size that is equal to or greater than that of the first redistribution pad 112p, depending on the circuit design.

A manufacturing method of the semiconductor package 10 described above will be described in detail with reference to FIG. 5A to FIG. 5H. FIG. 5A to FIG. 5H illustrate schematic cross-sectional views of a manufacturing method of the semiconductor package 10, according to an embodiment. The manufacturing method of the semiconductor package 10, according to an embodiment, may include a method of manufacturing the redistribution structure 100 or the redistribution substrate used in the semiconductor package 10.

As shown in FIG. 5A, a sacrificial layer 172 and a first insulating layer 114 having a via hole 150v may be formed on a carrier substrate 170.

The carrier substrate 170 supports a plurality of redistribution layers (e.g., reference numeral 102 in FIG. 5F) and a plurality of insulating layers (e.g., reference numeral 104 in FIG. 5F) forming the redistribution structure (e.g., reference numeral 100 in FIG. 5F, hereinafter the same) in the process of forming the redistribution structure 100. The carrier substrate 170 may include various materials that may be easily removed or peeled off after the redistribution structure 100 is formed. The carrier substrate 170 may include or be an insulating layer, a metal layer, or a plurality of layers having various characteristics or materials. As such, the embodiment is not necessarily limited to the material or structure of the carrier substrate 170.

The sacrificial layer 172 disposed on the carrier substrate 170 is a layer for forming the under bump pads 152 protruding from the lower surface 100a of the first insulating layer 114, and may be including a first via hole 152v corresponding to a portion in which the under bump pad 152 is to be disposed. The sacrificial layer 172 may include or be made of a material that has a selectivity to the under bump pattern 150a with respect to an etching material and that may be selectively removed by an etching process after the process of forming the redistribution structure 100. The sacrificial layer 172 may include or be an insulating layer, a metal layer, or a plurality of layers having various characteristics or materials. As such, the embodiment is not necessarily limited to the material or structure of the sacrificial layer 172.

The first insulating layer 114 disposed on the sacrificial layer 172 may include a second via hole 154v corresponding to the under bump via 154. The first insulating layer 114 may be formed by forming an insulating material on the sacrificial layer 172 by a method such as coating.

The sacrificial layer 172 and the first insulating layer 114 including the via hole 150v may be formed by various methods. For example, the sacrificial layer 172 having the first via hole 152v is formed, the first insulating layer 114 is entirely formed on the carrier substrate 170 and the sacrificial layer 172, and then the second via hole 154v may be formed by patterning the first insulating layer 114. In this case, in the process of forming the sacrificial layer 172 having the first via hole 152v, the sacrificial layer 172 is entirely formed and then the first via hole 152v may be formed by a patterning process, or the sacrificial layer 172 may be formed while having the first via hole 152v. Alternatively, after entirely forming the sacrificial layer 172 and the first insulating layer 114, the second via hole 154v and the first via hole 152v may be sequentially formed, or the second via hole 154v and the first via hole 152v may be formed together. Various other variations are possible.

Then, as shown in FIG. 5B, at least a portion of the under bump pattern 150a may be formed on the first insulating layer 114.

The under bump pattern 150a may be formed by various methods. For example, the under bump pattern 150a may be formed by a plating process using a first mask layer 174. Then, the under bump pattern 150a having a desired shape may be formed at a desired position by a simple process.

More specifically, the first mask layer 174 may be formed on the first insulating layer 114 to expose the via hole 150v. For example, after a first mask material layer is entirely formed on the upper surface of the carrier substrate 170, inside the via hole 150v of the sacrificial layer 172 and the first insulating layer 114, and on the upper surface of the first insulating layer 114, the first mask layer 174 may be formed by removing a portion in which the via hole 150v is disposed through a patterning process. For example, the first mask layer 174 or the first mask material layer may include or be made of a photoresist material, and the first mask material layer may be patterned by a photoresist process. However, the embodiment is not necessarily limited thereto. The first mask layer 174 may have a pattern, and the first mask layer 174 might not include a photoresist material. Various other variations are possible.

In an embodiment, the under bump pad 152 disposed in the first via hole 152v of the sacrificial layer 172 and the under bump via 154 disposed in the second via hole 154v of the first insulating layer 114 may be formed together. In this way, the under bump pad 152 and the under bump via 154 forming the under bump pattern 150a may be formed together by using the sacrificial layer 172, thereby simplifying the process. However, the embodiment is not necessarily limited thereto, and other examples will be described in detail later with reference to FIG. 6 and FIG. 7A to FIG. 7D.

After forming the under bump pattern 150a, the first mask layer 174 may be removed. As a process for removing the first mask layer 174, various processes such as an etching process may be used.

Subsequently, as shown in FIG. 5C, a second mask layer 176 for forming the first redistribution layer (e.g., reference numeral 112 in FIG. 5D, the same hereinafter) may be formed on the first insulating layer 114 and the under bump pattern 150a.

In an embodiment, the second mask layer 176 may include a first mask portion 176a formed on the under bump pattern 150a to correspond to a portion in which the partition (e.g., reference numeral 110 in FIG. 5E, hereinafter the same) is to be formed. The second mask layer 176 may include a second mask portion 176b formed on the first insulating layer 114 to correspond to a portion where the first redistribution layer 112 is not disposed. For example, the second mask portion 176b may correspond to a portion where a lower insulating layer (e.g., reference numeral 124a in FIG. 5E, hereinafter the same) of the second insulating layer (e.g., reference numeral 124 in FIG. 5F, hereinafter the same) will be formed. Here, the second mask portion 176b may be formed in an area other than a portion where the first redistribution pad (e.g., reference numeral 112p in FIG. 5D, hereinafter the same) and the first wire portion (e.g., reference numeral 112w in FIG. 5D, hereinafter the same) forming the first redistribution layer 112 are to be disposed.

For example, after the second mask material layer is entirely formed on the first insulating layer 114 and the under bump pattern 150a, a portion other than a portion where the first redistribution layer 112 is to be formed may be removed by a patterning process to form the second mask layer 176. For example, the second mask layer 176 or the second mask material layer may include or be made of a photoresist material, and the second mask material layer may be patterned by a photoresist process. However, the embodiment is not necessarily limited thereto. The second mask layer 176 may have a pattern, and the second mask layer 176 might not include a photoresist material. Various other variations are possible.

Subsequently, as shown in FIG. 5D, the first redistribution layer 112 may be formed on the under bump pattern 150a and the first insulating layer 114 in a portion where the second mask layer 176 is not formed. More specifically, the first redistribution layer 112 including the first redistribution pad 112p disposed on the under bump pattern 150a and formed in a portion other than the first mask portion 176a may be formed. In this case, the first redistribution layer 112 may further include the first wire portion 112w.

In this case, the first redistribution pad 112p might not be disposed on the under bump pattern 150a at a portion where the first mask portion (e.g., reference numeral 176a in FIG. 5C, hereinafter the same) of the second mask layer 176 is disposed. A portion where the first redistribution pad 112p is not disposed on the under bump pattern 150a may be a trench portion 110t disposed inside the first redistribution pad 112p after the second mask layer 176 is removed.

The first redistribution layer 112 may be formed by various methods. For example, the first redistribution layer 112 may be formed by a plating process using the second mask layer 176. Then, the first redistribution layer 112 having a desired shape may be formed at a desired position through a simple process.

As described above, after forming the first redistribution layer 112, the second mask layer 176 may be removed. As a process for removing the second mask layer 176, various processes such as an etching process may be used.

Subsequently, as shown in FIG. 5E, the partition 110 may be formed in the trench portion (e.g., reference numeral 110t in FIG. 5E, hereinafter the same) formed by removing the first mask portion 176a. In this case, the lower insulating layer 124a that is a portion of the second insulating layer 124 may be formed together in the portion from which the second mask portion 176b is removed.

More specifically, an insulating material layer may be entirely formed on the first insulating layer 114 and/or the first redistribution layer 112 while filling the trench portion 110t from which the first mask portion 176a is removed and the portion from which the second mask portion 176b is removed. The insulating material layer may be formed by various methods such as coating.

For example, in the process of forming the insulating material layer, the insulating material layer may be formed such that the upper surface of the insulating material layer is disposed on the same plane as the upper surface of the first redistribution layer 112 by adjusting process conditions.

As another example, in the process of forming the insulating material layer, the insulating material layer may be formed such that the upper surface of the insulating material layer is disposed higher than the upper surface of the first redistribution layer 112. In this case, a portion protruding above the upper surface of the first redistribution layer 112 at a portion of the insulating material layer disposed in the trench portion 110t may be exposed and partially removed. According to this, the upper surface of the partition 110 and the upper surface of the first redistribution layer 112 may be disposed on the same plane. In this case, the upper surface of the lower insulating layer 124a may be maintained at a higher position than the upper surface of the first redistribution layer 112, and a process of partially removing the protruding portion may be performed so that the upper surface of the lower insulating layer 124a may be disposed on the same plane as the upper surface of the first redistribution layer 112. However, the embodiment is not necessarily limited thereto. As a modified example, the next process may be performed with the upper surface of the partition 110 disposed higher than the upper surface of the first redistribution layer 112. This is because even if the upper surface of the partition 110 is disposed higher than the upper surface of the first redistribution layer 112, the upper portion (for example, the protruding portion) of the partition 110 may be surrounded by the second contact via 126.

The above-described insulating material layer may be thermally cured at a temperature higher than room temperature to form the partition 110 and the lower insulating layer 124a. Here, a portion of the insulating material layer disposed inside the trench portion 110t may form or configure the partition 110, and another portion of the insulating material layer disposed at a portion from which the second mask portion 176b is removed may form or configure the lower insulating layer 124a. As such, the reaction of the partition 110 and the lower insulating layer 124a formed by performing the curing process on the insulating material layer is completed, and the partition 110 and the lower insulating layer 124a might not be affected by a patterning process to be performed later.

In this way, the partition 110 and the lower insulating layer 124a may be formed together in the same process to simplify the manufacturing process of the redistribution structure 100 including the partition 110. However, the embodiment is not necessarily limited thereto, and the partition 110 may be formed in a separate process that is different from that of the lower insulating layer 124a or the second insulating layer 124. For example, after first forming the partition 110, the lower insulating layer 124a or the second insulating layer 124 may be formed. Alternatively, after first forming the lower insulating layer 124a or the second insulating layer 124, the partition 110 may be formed.

Subsequently, as shown in FIG. 5F, the second and third redistribution layers 122 and 132, the second connection pad 160, and the second to fourth insulating layers 124, 134, and 144 may be formed on the first redistribution pad 112p and the partition 110 to manufacture the redistribution structure 100. In addition, the semiconductor chip 200 may be mounted on the upper surface 100b of the redistribution structure 100, and the sealant 220 may be formed.

More specifically, the second contact via 126 may be formed on the first redistribution pad 112p and the partition 110. For example, the second insulating layer 124, the second contact via 126, and the second redistribution layer 122 may be formed on the first insulating layer 114, the first redistribution pad 112p, and the partition 110. The third insulating layer 134, the third contact via 136, and the third redistribution layer 132 are formed thereon, and the fourth insulating layer 144, the fourth contact via 146, and the second connection pad 160 may be formed.

The second to fourth insulating layers 124, 134, and 144, the second to fourth contact vias 126, 136, and 146, the second and third redistribution layers 122 and 132, and the second connection pads 160 may be formed in various process sequences by various methods.

For example, after forming the upper insulating layer 124b of the second insulating layer 124, a via hole exposing the first redistribution pad 112p may be formed. The via hole may be formed by a photoresist process and an etching process. In this case, since the partition 110 is cured and the reaction is completed, even if a patterning process or an etching process is performed on the upper insulating layer 124b, the partition 110 may remain as it is without reacting. In addition, after forming the second contact via 126 by forming a metal material inside the via hole, the second redistribution layer 122 may be formed by using a mask layer. As another example, the second contact via 126 and the second redistribution layer 122 may be formed together after forming a mask layer.

The third insulating layer 134, the third contact via 136, and the third redistribution layer 132 may be formed on the second redistribution layer 122. Unlike the second insulating layer 124, the third insulating layer 134 may be configured as an insulating layer formed in one process without distinction between an upper insulating layer and a lower insulating layer. After a via hole exposing the second redistribution layer 122 is formed in the third insulating layer 134 and a mask layer for forming the third redistribution layer 132 is formed on the third insulating layer 134, the third contact via 136 and the third redistribution layer 132 may be formed together. According to this, the formation process of the third insulating layer 134, the third contact via 136, and the third redistribution layer 132 may be simplified. However, the embodiment is not necessarily limited thereto. Accordingly, similar to the second insulating layer 124, the third insulating layer 134 may be formed by separately forming the upper insulating layer and the lower insulating layer. After the third contact via 136 is first formed in the via hole formed in the third insulating layer 134, the third redistribution layer 132 may be formed by using a mask layer. Various other variations are possible.

In addition, the fourth insulating layer 144, the fourth contact via 146, and the second connection pad 160 may be formed on the third redistribution layer 132. Unlike the second insulating layer 124, the fourth insulating layer 144 may be configured as an insulating layer formed in one process without distinction between an upper insulating layer and a lower insulating layer. After a via hole exposing the third redistribution layer 132 is formed in the fourth insulating layer 144 and a mask layer for forming the second connection pad 160 is formed on the fourth insulating layer 144, the fourth contact via 146 and the second connection pad 160 may be formed together. According to this, the formation process of the fourth insulating layer 144, the fourth contact via 146, and the second connection pad 160 may be simplified. However, the embodiment is not necessarily limited thereto. Accordingly, similar to the second insulating layer 124, the fourth insulating layer 144 may be formed by separately forming the upper insulating layer and the lower insulating layer. After the fourth contact via 146 is first formed in the via hole formed in the fourth insulating layer 144, the second connection pad 160 may be formed by using a mask layer. Various other variations are possible.

Subsequently, the semiconductor chip 200 may be mounted on the upper surface 100b of the redistribution structure 100 by using the connector 230, and the sealant 220 may be formed. In this case, the connection member 230 may be disposed between the second connection pad 160 and the connection pad 210 to physically and electrically connect them. Various processes may be used as a process for forming the sealant 220.

Subsequently, as shown in FIG. 5G, the carrier substrate (e.g., reference numeral 170 in FIG. 5F, hereinafter the same) and the sacrificial layer (e.g., reference numeral 172 in FIG. 5F, hereinafter the same) may be removed. For example, the carrier substrate 170 may be separated or removed by a peeling process or an etching process, and the sacrificial layer 172 may be removed by an etching process. In the process of removing the carrier substrate 170 and/or the sacrificial layer 172, an etching material capable of selectively removing the carrier substrate 170 and/or the sacrificial layer 172 without removing the first insulating layer 114 and the under bump pattern 150a may be used.

Subsequently, as shown in FIG. 5H, the connection bump 300 may be formed in the first connection pad 150 of the under bump patterns 150a. Various processes may be used as a process of forming the connection bump 300.

According to an embodiment, the redistribution structure 100 including the partition 110 disposed inside a relatively large first redistribution pad 112p may be formed by a simple process by using the second mask layer 176 including the first mask portion 176a. In this case, in the process of forming the partition 110, a portion of the second insulating layer 124 (for example, the lower insulating layer 124a) may be formed together to simplify the manufacturing process.

Hereinafter, a semiconductor package, according to an embodiment that is different from the above-described embodiment, will be described in more detail with reference to FIG. 6 and FIG. 7A to FIG. 7D. To the extent that an element is not described in detail below, it may be understood that the element is at least similar to a corresponding element that has been described elsewhere within the present disclosure.

FIG. 6 illustrates a schematic cross-sectional view of a semiconductor package according to an embodiment.

Referring to FIG. 6, in the semiconductor package, according to an embodiment, the under bump pad 152 may have a larger area or size (e.g., diameter or width) than the under bump via 154. According to this, the connection bump 300 disposed on the under bump pad 152 may be more stably disposed.

In the illustrative embodiment, the under bump pad 152 may be formed in a separate process from the under bump via 154, and for example, the under bump pad 152 may be formed after the formation process of the under bump via 154 or the formation process of the semiconductor chip 200. However, the embodiment is not necessarily limited thereto.

A manufacturing method of the semiconductor package described above will be described in detail with reference to FIG. 7A to FIG. 7D. FIG. 7A to FIG. 7D illustrate schematic cross-sectional views of a manufacturing method of a semiconductor package according to an embodiment. The manufacturing method of the semiconductor package, according to an embodiment, may include a manufacturing method of the redistribution structure 100 or the redistribution substrate used in the semiconductor package.

As shown in FIG. 7A, the first to fourth insulating layers 114, 124, 134, and 144, the under bump via 154, the first to third redistribution layers 112, 122, and 132, and the second connection pads 160 may be formed on the carrier substrate 170 to form the redistribution structure 100 excluding the under bump pad 152, the semiconductor chip 200 may be mounted on the upper surface 100b of the redistribution structure 100, and the sealant 220 may be formed.

Except for not forming the sacrificial layer 172 and the under bump pad 152, the descriptions with reference to FIG. 5A to FIG. 5F may be applied as they are.

Subsequently, as shown in FIG. 7B, after separating or removing the carrier substrate 170, as shown in FIG. 7C, the under bump pad 152 may be formed on the lower surface 100a of the redistribution structure 100. The under bump pad 152 may be formed by a plating process by using a mask layer, or may be formed by various other processes.

Subsequently, as shown in FIG. 7D, the connection bump 300 may be formed in the first connection pad 150 of the under bump patterns 150a. Various processes may be used as a process of forming the connection bump 300.

As described above, the structure and manufacturing method of the semiconductor package, according to an embodiment, may be variously changed.

While embodiment of the present disclosure has been described in connection with what is presently considered to be practical embodiments, it is to be understood that the disclosure is not necessarily limited to the disclosed embodiments, but, on the contrary, is intended to cover various modifications and equivalent arrangements included within the spirit and scope of the present disclosure.

What is claimed is:

1. A semiconductor package, comprising:
a semiconductor chip; and
a redistribution structure connected to the semiconductor chip,
wherein the redistribution structure includes:
an under bump pattern;
a first redistribution layer disposed on the under bump pattern and including a first redistribution pad;
a partition disposed inside the first redistribution pad and comprising a material that is different from a material of the first redistribution pad;
a contact via disposed on the first redistribution pad and the partition; and
a second redistribution layer including a second redistribution pad disposed on the contact via.

2. The semiconductor package of claim 1, wherein
the partition comprises an insulating material.

3. The semiconductor package of claim 1, wherein
the partition has a smaller thermal shrinkage rate than the first redistribution pad.

4. The semiconductor package of claim 1, wherein
the redistribution structure further includes an insulating layer, and
the partition is disposed on a same layer as at least a portion of the insulating layer and includes a same material as at least a portion of the insulating layer.

5. The semiconductor package of claim 4, wherein
the insulating layer includes a first insulating layer having a first surface on which the under bump pattern is exposed and a second surface on which the first redistribution layer is disposed, and a second insulating layer including a lower insulating layer disposed on a same layer as the first redistribution pad on the first insulating layer, and
the partition comprises a same material as the lower insulating layer.

6. The semiconductor package of claim 1, wherein
the partition is disposed at a central portion of the first redistribution pad.

7. The semiconductor package of claim 1, wherein
the partition is disposed inside the under bump pattern or the contact via.

8. The semiconductor package of claim 1, wherein
the partition is entirely surrounded by the first redistribution pad, the contact via, and the under bump pattern.

9. The semiconductor package of claim 1, wherein
a ratio of an area of the partition to an area of the contact via is 60% or lower.

10. The semiconductor package of claim 1, wherein
an area of the partition is smaller than a connection area between the contact via and the first redistribution pad.

11. The semiconductor package of claim 1, wherein
the partition has a loop shape extending along an outer edge of the first redistribution pad.

12. The semiconductor package of claim 11, wherein
the first redistribution pad includes an outer portion disposed outside the partition and an inner portion disposed inside the partition.

13. The semiconductor package of claim 1, wherein
an entire width or a line width of the partition is greater than a thickness of the partition.

14. The semiconductor package of claim 1, wherein
a side surface of the under bump pattern includes inclined surface gradually decreasing in size from the first redistribution layer toward a lower surface of the redistribution structure.

15. A redistribution substrate for a semiconductor package, comprising:
an under bump pattern;
a first redistribution layer disposed on the under bump pattern and including a first redistribution pad;
a separation insulating portion disposed inside the first redistribution pad and comprising an insulating material having a smaller thermal shrinkage rate than that of the first redistribution pad;
a contact via disposed on the first redistribution pad and the separation insulating portion; and
a second redistribution layer including a second redistribution pad connected to the contact via.

16. The redistribution substrate for the semiconductor package of claim 15, wherein
the separation insulating portion is entirely surrounded by metal included in the first redistribution pad, the contact via, and the under bump pattern.

17. The redistribution substrate for the semiconductor package of claim 15, wherein
the separation insulating portion is disposed at a central portion of the contact via.

18. A manufacturing method of a redistribution substrate for a semiconductor package, comprising:
forming at least a portion of an under bump pattern on a first insulating layer;
forming a mask layer including a first mask portion on the under bump pattern;
forming a first redistribution layer including a first redistribution pad disposed on a portion other than the first mask portion on the under bump pattern;
removing the mask layer;
forming a partition in a portion from which the first mask portion is removed inside the first redistribution pad; and
forming a contact via on the first redistribution pad and the partition.

19. The manufacturing method of the redistribution substrate for the semiconductor package of claim 18, wherein
in the forming of the mask layer, the mask layer further includes a second mask portion formed on the first insulating layer corresponding to a portion in which the first redistribution layer is not disposed, and
in the step of forming the partition, a portion of the second insulating layer is formed together in a portion from which the second mask portion is removed.

20. The manufacturing method of the redistribution substrate for the semiconductor package of claim 18, wherein
the partition includes an insulating material.
